(19) United States
(12) Patent Application Publication
(10) Pub. No.: US 2023/0380017 A1
(43) Pub. Date: Nov. 23, 2023

(54) CERAMIC HEATER

(71) Applicant: Niterra Co., Ltd., Nagoya-shi (JP)

(72) Inventor: Kazuya TAKAHASHI, Nagoya-shi (JP)

(21) Appl. No.: 18/320,562

(22) Filed: May 19, 2023

(30) Foreign Application Priority Data
May 20, 2022 (JP) 2022-083130

(51) Int. Cl. H05B 3/28; G01K 1/02

(52) U.S. Cl. CPC H05B 3/283; G01K 1/026; H05B 2203/005; H01L 21/67109

(57) ABSTRACT

There is provided a ceramic heater including: a ceramic base member including: an upper surface and a lower surface opposite to the upper surface in an up-down direction; a plurality of heating elements embedded in the ceramic base member, and a plurality of temperature sensors each including a temperature sensing portion that is embedded in the ceramic base member. The temperature sensing portion of at least one of the plurality of temperature sensors is positioned in a location that does not overlap with the plurality of heating elements in the up-down direction.

### REFERENCE TO RELATED APPLICATIONS

This application claims priority from Japanese Patent Application No. 2022-083130 filed on May 20, 2022. The entire content of the priority application is incorporated herein by reference.

### BACKGROUND ART

### Technical Field

This disclosure relates to a ceramic heater for heating a substrate such as a silicon wafer.

### Background Art

A publicly known ceramic heater includes a disc-shaped ceramic substrate (ceramic base member), a heating element (heating resistor) embedded in the ceramic substrate, and a thermocouple.

### DESCRIPTION

### Problem to be Solved by the Invention

In the ceramic heater described above, the temperature-sensing portion of the thermocouple is located between the heating element and the surface of the ceramic substrate.

Therefore, the temperature of a wafer placed on the surface of the ceramic substrate can be accurately measured using the thermocouple.

In recent years, there has been a growing demand for ceramic heaters that can further equalize the temperature of wafers.

An object of the present disclosure is to provide a ceramic heater capable of improving the temperature uniformity of wafers to be heated.

According to an aspect of the present disclosure, there is provided a ceramic heater including: a ceramic base member including: an upper surface and a lower surface opposite to the upper surface in an up-down direction; a plurality of heating elements embedded in the ceramic base member; and a plurality of temperature sensors each including a temperature sensing portion embedded in the ceramic base member. The temperature sensing portion of at least one of the plurality of temperature sensors is positioned in a location not overlapping with the plurality of heating elements in the up-down direction.

In this situation, the temperature of the ceramic base member can be controlled by using the temperature sensor in which the temperature sensing portion is arranged in a position that does not overlap with the plurality of heating elements in the up-down direction. This can contribute to improving the temperature uniformity of a wafer to be heated, such as a silicon wafer for temperature evaluation, for example.

### BRIEF DESCRIPTION OF THE DRAWINGS

FIG. 1 is a diagram of a ceramic heater 100.

FIG. 2 is a schematic illustration of the ceramic heater 100.

FIG. 3A depicts the inner heater electrode 120, FIG. 3B depicts the outer heater electrode 122, and FIG. 3C depicts the electrostatic adsorption electrode 124.

FIG. 4 depicts the shape of the shaft 130.

FIGS. 5A to 5E depict the flow of the manufacturing method of the ceramic base member 110.

FIG. 6 indicates a table summarizing the results of Examples 1-15.

FIG. 7 depicts the ceramic heater 100 of Example 1.

FIG. 8 depicts the ceramic heater 100 of Example 3.

FIG. 9 depicts the opening 120h of the inner heater electrode 120 of the ceramic heater 100 of Example 12.

FIG. 10 depicts the curved portion C1 of the TC-hole 170 of the ceramic heater 100 of Example 13.

FIG. 11 depicts the curved portion C2 of the TC-hole 170 of the ceramic heater 100 of Example 14.

FIG. 12 depicts the ceramic heater 100 of Example 15.

FIG. 13 depicts the ceramic heater 100 in which the outer heater electrode 122 is arranged above the inner heater electrode 120.

### DESCRIPTION OF THE EMBODIMENT

<Ceramic Heater 100>

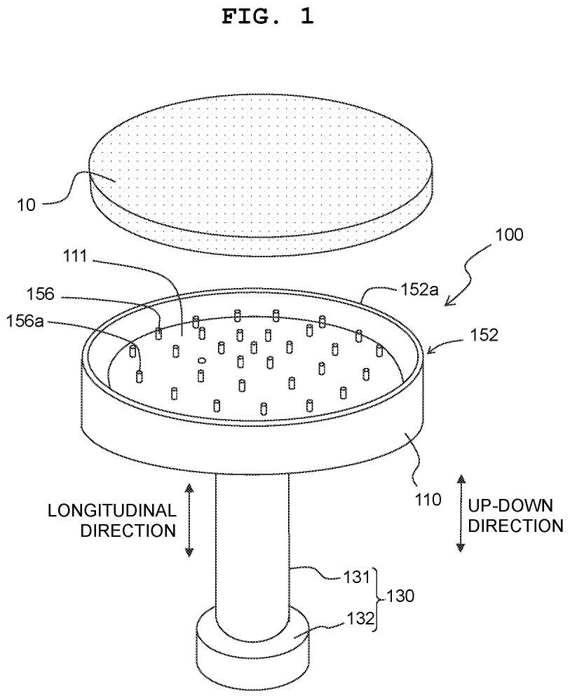

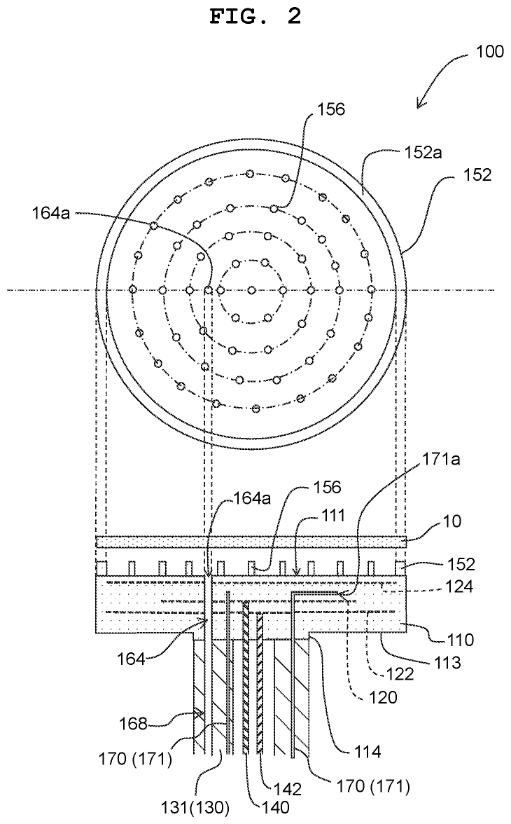

The ceramic heater 100, according to an embodiment of the present disclosure, will be described with reference to FIGS. 1 and 2. The ceramic heater 100, according to the present embodiment, is used for heating a semiconductor wafer (hereinafter referred to as a wafer 10) such as a silicon wafer, etc. In the following description, an up-down direction is defined based on the state in which the ceramic heater 100 is installed usably (a state depicted in FIG. 1). As depicted in FIG. 1, the ceramic heater 100 in this embodiment includes a ceramic base member 110, electrodes (an inner heater electrode 120, an outer heater electrode 122, electrostatic adsorption electrodes 124 (see FIG. 2)), a shaft 130, feed wires 140, 142 (see FIG. 2), a thermocouple 171 as a temperature sensor (see FIG. 2).

The ceramic base member 110 has a circular plate shape with a diameter of 12 inches (about 300 mm), and a wafer 10 to be heated is placed on the ceramic base member 110. In FIG. 1, the wafer 10 and the ceramic base member 110 are illustrated to be separated from each other such that the drawing is easily viewed. As depicted in FIG. 1, the upper surface 111 of the ceramic base member 110 is provided with a convex portion 152 having an annular shape (hereinafter referred to as the annular convex portion 152) and a plurality of convex portions 156. In FIG. 1, the number of the plurality of convex portions 156 is reduced to make the drawing easier to read. As depicted in FIG. 2, a first gas flow path 164, described below, is formed inside the ceramic base member 110. For example, the ceramic base member 110 can be formed by sintered ceramics such as aluminum nitride, silicon carbide, alumina, silicon nitride, etc.

As depicted in FIGS. 1 and 2, the annular convex portion 152 is an annular-shaped convex portion disposed on the periphery (outer edge) of the upper surface 111 of the ceramic base member 110 and protruding upward from the upper surface 111. As depicted in FIG. 2, when the wafer 10 is placed on the ceramic base member 110, the upper surface 152a of the annular convex portion 152 contacts the lower surface of the wafer 10. In other words, the annular convex portion 152 overlaps the wafer 10 in the up-down direction when the wafer 10 is placed on the ceramic base member 110. A plurality of convex portions 156 is provided on the upper surface 111 of the ceramic base member 110, inside the annular convex portion 152. The plurality of convex portions 156 has a cylindrical shape. As depicted in FIG. 2, one of the plurality of convex portions 156 is located at the approximate center of the upper surface 111. The remaining convex portions 156 are arranged on the circumference of four equally spaced concentric circles. The convex portions 156 are equally spaced on the circumference of each of the concentric circles. Positions of the concentric circles and/or the number of the concentric circles in which the convex portions 156 are arranged are set appropriately according to the application, action, and function.

The height of the annular convex portion 152 can range from 5 μm to 2 mm. Similarly, the height of the plurality of convex portions 156 can be in the range of 5 μm to 2 mm. In this embodiment, the height of the annular convex portion 152 is equal to the height of the plurality of convex portions 156. In other words, the upper surface 152a of the annular convex portion 152 and the upper surface 156a of the plurality of convex portions 156 are flush. In the present specification, the height of the annular convex portion 152 and the plurality of convex portions 156 are defined as the length in the up-down direction from the upper surface 111 of the ceramic base member 110. Suppose the upper surface 111 of the ceramic base member 110 is not flat and has a step, for example. In that case, the upper surface 111 of the ceramic base member 110 is defined as the length in the vertical direction from the highest position of the upper surface 111 of the ceramic base member 110.

The width of the upper surface 152a of the annular convex portion 152 should be constant and can be 0.1 mm to 10 mm. The surface roughness Ra (the center line average roughness Ra) of the upper surface 152a of the annular convex portion 152 can be 1.6 μm or less. Similarly, the surface roughness Ra (the center line average roughness Ra) of the upper surface 156a of the plurality of convex portions 156 can be 1.6 μm or less. The surface roughness Ra of the upper surface 152a of the annular convex portion 152 and the upper surface 156a of the plurality of convex portions 156 is preferably 0.4 μm or less and is more preferably 0.2 μm or less.

The upper surface 156a of the plurality of convex portions 156 is preferably circular with a diameter of 0.1 mm to 5 mm. The distance between each convex portion of the plurality of convex portions 156 can range from 1.5 mm to 30 mm. As described above, on the upper surface 111 of the ceramic base member 110, the plurality of convex portions 156 are aligned on the circumference of four concentric circles. As depicted in FIG. 2, an opening 164a of the first gas flow path 164 opens between the innermost concentric circle and the second concentric circle from the inner side of the upper surface 111. The first gas flow path 164 is a gas flow path provided with an opening 164a and is formed inside the ceramic base member 110. The first gas flow path 164 extends downward from the opening 164a. As depicted in FIG. 2, the lower end of the first gas flow path 164 is joined to the upper end of the second gas flow path 168 formed inside the shaft 130. The first gas flow path 164 can be used to supply gas to the space (gap) defined by the upper surface 111 of the ceramic base member 110 and the lower surface of the wafer 10. For example, a heat transfer gas can be supplied for heat transfer between the wafer 10 and the ceramic base member 110. For example, an inert gas such as helium, argon, or nitrogen gas can be used as a heat transfer gas. The heat transfer gas is supplied through the first gas flow path 164 at a pressure set within the range of 100 Pa to 4000 Pa. If process gases enter the gap between the upper surface 152a of the annular convex portion 152 and the lower surface of the wafer 10, the gases can be exhausted through the first gas flow path 164. In this case, the differential pressure between the pressure outside the gap and inside the gap can be adjusted by adjusting the exhaust pressure. This allows the wafer 10 to be adsorbed toward the upper surface 111 of the ceramic base member 110.

<Inner Heater Electrode 120 and Outer Heater Electrode 122>

As depicted in FIG. 2, an inner heater electrode 120, an outer heater electrode 122, and an electrode for electrostatic adsorption (an electrostatic absorption electrode 124) are buried inside the ceramic base member 110. In this specification, the inner heater electrode 120 and the outer heater electrode 122 are sometimes collectively referred to as the heater electrodes. The inner heater electrode 120, the outer heater electrode 122, and the electrostatic adsorption electrode 124 may collectively be referred to as the electrodes.

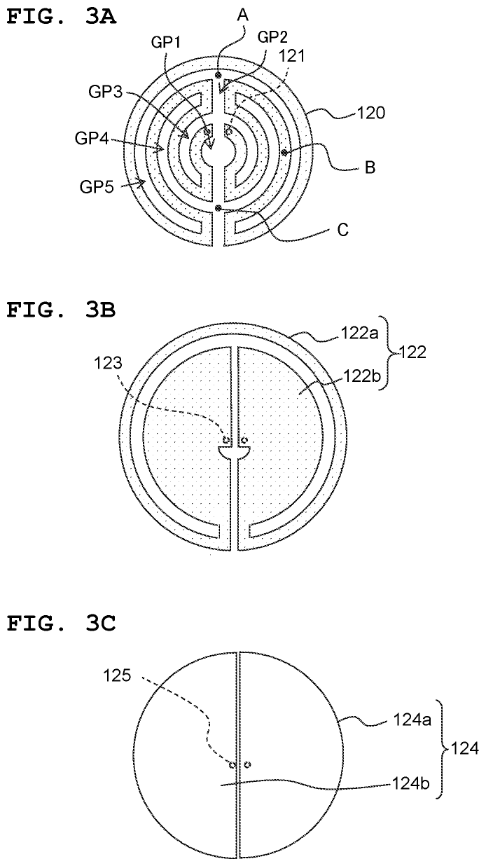

As depicted in FIG. 2, the inner heater electrode 120 is located above the outer heater electrode 122. The inner heater electrode 120 is formed by cutting a heat-resistant metal (a metal with a high melting point of 2000° C. or higher) such as a mesh or foil made of woven wire of tungsten (W), molybdenum (Mo) or an alloy containing molybdenum and/or tungsten into a strip shape as depicted in FIG. 3A. Similarly, the outer heater electrode 122 is formed by cutting a metal mesh or foil into a shape as depicted in FIG. 3B. As depicted in FIG. 3B, the outer heater electrode 122 has an abbreviated ring-shaped heater portion 122a and a conduction portion 122b disposed inside the heater portion 122a. The conduction portion 122b has lower resistance than the heater portion 122a and does not contribute much to heat generation. The conduction portion 122b has a half-moon shape concentric with the inner heater electrode 120. The conduction portion 122b and the inner heater electrode 120 are arranged to almost overlap in the top view, and the heater portion 122a surrounds the outside of the conduction portion 122b. The heater portions 122a of the inner heater electrode 120 and the outer heater electrode 122 are examples of the plurality of heating elements of the present disclosure. The inner heater electrode 120 is an example of an inner heating element of the present disclosure, and the heater portion 122a of the outer heater electrode 122 is an example of an outer heating element of the present disclosure.

In this embodiment, the outer diameter of the heater portion 122a of the outer heater electrode 122 is 298 mm, and the outer heater electrode 122 is not exposed from the side of the ceramic base member 110. At the center of the inner heater electrode 120 is a terminal 121 that is connected to the feed wire 140 (see FIG. 2). At the abbreviated center of the conductive portion 122b of the outer heater electrode 122, there is a terminal 123 that is connected to the power feed wire 141 (see FIG. 2). In addition, a cutout or runout is formed in the abbreviated center of the conduction portion 122b of the outer heater electrode 122 to pass an undepicted power feed wire connected to the electrostatic adsorption electrode 124. As described above, the inner heater electrode 120 and the outer heater electrode 122 are formed of heat-resistant metals (high-melting-point metals) such as tungsten (W), molybdenum (Mo), molybdenum and/or alloys containing tungsten wire woven mesh or foil. The purity of tungsten and molybdenum is preferably 99% or higher. The thickness of the inner heater electrode 120 and the outer heater electrode 122 is 0.15 mm or less. From the viewpoint of increasing the resistance of the heater portion 122a of the inner heater electrode 120 and the outer heater electrode 122, the wire diameter of the mesh wire is preferably 0.1 mm or less, or the thickness of the foil is preferably 0.1 mm or less. The width of the inner heater electrode 120 cut into strips and the width of the heater portion 122a of the outer heater electrode 122 is preferably in a range from 2.5 mm to 20 mm and is more preferably in a range from 5 mm to 15 mm. In this embodiment, the inner heater electrode 120 and the outer heater electrode 122 are cut into the shapes depicted in FIGS. 3A and 3B, but the shapes of the inner heater electrode 120 and the outer heater electrode 122 are not limited to this and can be changed as needed.

<Electrostatic Adsorption Electrodes 124>

As depicted in FIG. 2, the electrostatic adsorption electrodes 124 are buried above the inner heater electrode 120 and the outer heater electrode 122 inside the ceramic base member 110. As depicted in FIG. 3C, the electrostatic adsorption electrodes 124 include two semi-circular electrodes 124a and 124b arranged to face each other at a predetermined distance (5 mm) and have an overall shape of an abbreviated circle. The outer diameter of the electrostatic adsorption electrode 124 is 294 mm. The electrodes 124a and 124b of the electrostatic adsorption electrode 124 are each provided with a terminal 125 connected to an undepicted power supply line.

<Shaft 130 and Joining Convex Portion 114>

As depicted in FIGS. 1 and 2, a shaft 130 is connected to the lower surface 113 of the ceramic base member 110. The shaft 130 has a hollow, abbreviated cylindrical portion 131 and a large diameter portion 132 (see FIG. 1) provided below the cylindrical portion 131. The large diameter portion 132 has a diameter larger than that of the cylindrical portion 131. In the following description, the longitudinal direction of the cylindrical portion 131 is defined as the longitudinal direction of the shaft 130. As depicted in FIG. 1, in the state of use of the ceramic heater 100, the longitudinal direction of the shaft 130 is parallel to the up-down direction. The lower surface 113 of the ceramic base member 110 may be a flat surface, or it may be provided with a convex portion 114 for joining with the shaft 130 (hereinafter referred to as the joining convex portion 114), as depicted in FIG. 2. The shape of the joining convex portion 114 is preferably the same as the shape of the upper surface of the shaft 130 to be joined, and the diameter of the joining convex portion 114 is preferably 100 mm or less. The height of the joining convex portion 114 (a length from the lower surface 113) is preferably 0.2 mm or more and is more preferably 5 mm or more. There is no particular upper limit to the height, but considering the ease of fabrication, the height of the joining convex portion 114 is preferably 20 mm or less. The lower surface of the joining convex portion 114 is preferably parallel to the lower surface 113 of the ceramic base member 110. The surface roughness Ra of the lower surface of the joining convex portion 114 can be 1.6 μm or less. The surface roughness Ra of the lower surface of the joining convex portion 114 is preferably 0.4 μm or less and is more preferably 0.2 μm or less.

The upper surface of the cylindrical portion 131 is fixed to the lower surface 113 of the ceramic base member 110 (or the lower surface of the joining convex portion 114, if the joining convex portion 114 is provided). The shaft 130 may be formed of sintered ceramics such as aluminum nitride, silicon carbide, alumina, silicon nitride, or the like, as the ceramic base member 110. Alternatively, it may be formed of a material with a lower thermal conductivity than the ceramic base member 110 to improve thermal insulation. As depicted in FIG. 4, a diameter-expanding portion 133 similar to the large-diameter portion 132 below the cylindrical portion 131 may be provided on the upper surface of the cylindrical portion 131. For example, the outer diameter of the large diameter portion 132 can be the same as the outer diameter of the joining convex portion 114.

As depicted in FIG. 2, the shaft 130 has a hollow cylindrical shape, and a through hole extending in the longitudinal direction (see FIG. 1) is formed in the interior (region inside the inner diameter) of the shaft 130. The feeder wires 140 for supplying power to the inner heater electrode 120 and the feeder wires 142 for supplying power to the outer heater electrode 122 are arranged in the hollow portion (through hole) of the shaft 130. Although not depicted in the figures, another power feeder wire connected to the terminal 125 of the electrostatic adsorption electrode 124 (see FIG. 3C) is also located in the hollow portion (through hole) of the shaft 130. The top end of the feeder wire 140 is electrically connected to the terminal 121 (see FIG. 3A), located in the center of inner heater electrode 120. Similarly, the upper end of feeder wire 142 is electrically connected to the terminal 123 (see FIG. 3B), located in the center of outer heater electrode 122. The feeder wires 140 and 142 are connected to an undepicted power supply for the heater. This allows electric power to be supplied to the inner heater electrode 120 and the outer heater electrode 122 individually via the feeder wires 140 and 142.

As depicted in FIG. 2, a second gas flow path 168 extending in the up-down direction is formed in the cylindrical portion 131 of the shaft 130. As described above, the upper end of the second gas flow path 168 is connected to the lower end of the first gas flow path 164. A portion of TC-holes 170 for inserting the thermocouples 171 is formed in the cylindrical portion 131 of the shaft 130.

<Thermocouples 171>

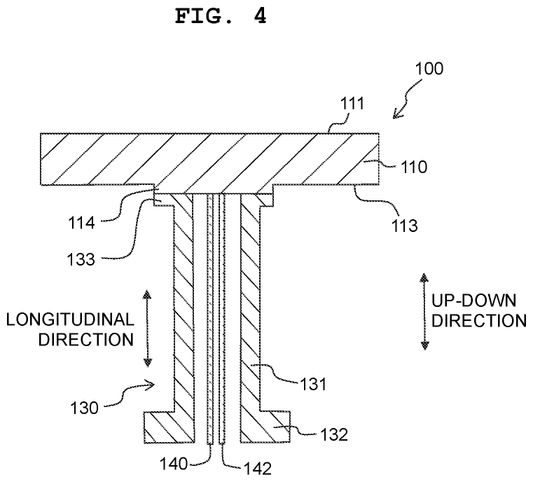

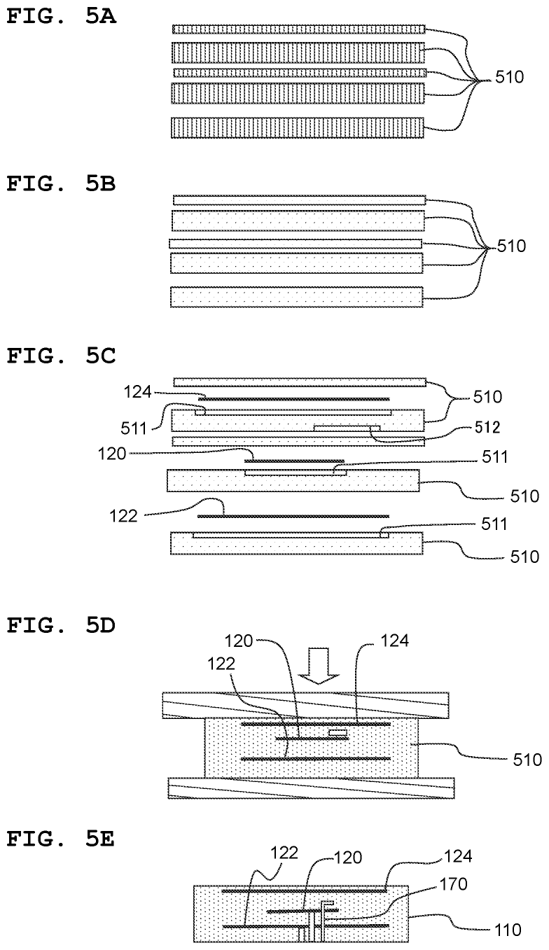

As depicted in FIG. 2, the cylindrical portion 131 of the shaft 130 and the ceramic base member 110 have TC-holes 170 (see FIG. 5E) for inserting the thermocouples 171, and the thermocouples 171 are inserted along the TC-holes 170. Temperature-measuring contacts 171a are provided at the tip of the thermocouples 171, respectively. In this embodiment, a SUS sheathed thermocouple with a diameter of 1.6 mm is used as the thermocouple 171, and the diameter of the TC-hole 170 is 3 mm. The thermocouple 171 is an example of a temperature sensor, and the temperature-measuring contact 171a is an example of a temperature sensing portion of the present disclosure. In FIG. 2, two thermocouples 171 are illustrated, but in this embodiment, three thermocouples 171 are provided in the ceramic base member 110. The temperature-measuring contacts 171a of the thermocouples 171 can be placed at appropriate positions. In this embodiment, the TC-holes are formed so that the temperature-measuring contacts 171a are placed at positions A to C depicted in FIG. 3A. Positions A and C are positions that do not overlap with the inner heater electrode 120 in the up-down direction, and position B is a position that overlaps with the inner heater electrode 120 in the up-down direction. As depicted in FIG. 3A, the inner heater electrode 120 forms an abbreviated circular gap GP1 formed in the center, a linear gap GP2 extending radially through the gap GP1, and three arc-shaped gaps GP3 to GP5 concentrically surrounding the gap GP1. Position A corresponds to the intersection of the linear gap GP2 and the arc-shaped gap GP5, and position C corresponds to the intersection of the linear gap GP2 and the arc-shaped gap GP4.

<Manufacturing Method of the Ceramic Heater 100>

The manufacturing method of the ceramic heater 100 is described below. In the following, the case where the ceramic base member 110 and shaft 130 are formed of aluminum nitride will be explained as an example.

First, the manufacturing method of the ceramic base member 110 is described. As depicted in FIG. 5A, a granulated powder P mainly composed of aluminum nitride (AlN) powder, is CIP molded with a binder and processed into a disc shape to produce a plurality of aluminum nitride molded bodies (compacts) 510. The granulated powder P preferably contains 5 wt % or less of a sintering aid (e.g., Y₂O₃). As depicted in FIG. 5B, the molded body 510 is degreased to remove the binder.

As depicted in FIG. 5C, recesses 511 for burying the inner heater electrode 120, the outer heater electrode 122, and the electrostatic adsorption electrode 124 and the recesses 512 that are part of the TC-holes are formed in the degreased molded body 510. The recesses 511 and 512 may be formed in the molded bodies 510 in advance.

The inner heater electrode 120, the outer heater electrode 122, and the electrostatic adsorption electrode 124 are placed in the recess 511 of the molded body 510, and another molded body 510 is stacked on the molded body 510. Pellets formed by tungsten, molybdenum, or an alloy containing at least one of these materials may be buried at the position overlapping terminals 121 and 123 (see FIGS. 3A and 3B). When the pellets are buried, a paste of tungsten, molybdenum, or other high-melting-point metal powder may be applied between the inner heater electrode 120 and the pellet and between the outer heater electrode 122 and the pellet, as needed. This can improve the adhesion between the electrode and the pellet.

As depicted in FIG. 5D, a plurality of stacked molded bodies 510 are fired while pressed (uniaxial hot press firing) to produce a fired body. The pressure applied during firing is preferably 1 MPa or higher. It is also preferable to fire at a temperature of 1,800° C. or higher.

As depicted in FIG. 5E, stop holes are machined to the inner heater electrode 120 and the outer heater electrode 122 to form terminals 121 and 123. If pellets are buried, stop hole processing up to the pellets should be performed. In addition, stop-hole processing is performed to form the TC-holes 170. Further, a through hole that becomes a part of the first gas flow path 164 is formed. This allows the ceramic base member 110 with the first gas flow path 164 formed inside to be fabricated. In this case, a predetermined runout or cutout is provided on the electrode in advance so that the electrode is not exposed from the first gas flow path 164.

Grinding is performed on the upper surface 111 of the ceramic base member 110 formed this way, and lapping (mirror polishing process) is performed. Further, sandblasting is performed on the upper surface 111 to form a plurality of convex portions 156 and the annular convex portion 152 on the upper surface 111. Currently, the height of the annular convex portion 152 and the plurality of convex portions 156 are processed to be the same. Sandblasting is the preferred processing method for forming the plurality of convex portions 156 and the annular convex portion 152, but other processing methods can also be used. The lower surface 113 of the ceramic base member 110 may be provided with the joining convex portion 114 protruding from the lower surface 113.

Next, the method of manufacturing the shaft 130 and the method of joining the shaft 130 and the ceramic base member 110 will be described. First, granulated aluminum nitride powder P of aluminum nitride with a few wt % of binder added is shaped under hydrostatic pressure (about 1 MPa), and the molded body is processed into a predetermined shape. Currently, a through hole that serves as the second gas flow path 168 is formed in the molded body. The outer diameter of the shaft 130 is about 30 mm to 100 mm. The end face of the cylindrical portion 131 of the shaft 130 may be provided with a flange portion 133 having a diameter larger than the outer diameter of the cylindrical portion 131 (see FIG. 4). The length of the cylindrical portion 131 can be, for example, 50 mm to 500 mm. After the molded body is processed into a predetermined shape, the molded body is fired in a nitrogen atmosphere. For example, the molded body is fired at a temperature of 1900° C. for 2 hours to form a sintered body. The shaft 130 is then formed by processing the sintered body into a predetermined shape after firing. The upper surface of the cylindrical portion 131 and the lower surface 113 of the ceramic base member 110 can be fixed by diffusion bonding at 1600° C. or higher and under uniaxial pressure of 1 MPa or higher. In this case, the surface roughness Ra of the lower surface 113 of the ceramic base member 110 is preferably 0.4 μm or less and is more preferably 0.2 μm or less. The upper surface of the cylindrical portion 131 and the lower surface 113 of the ceramic base member 110 can be joined or bonded using a bonding agent. For example, a paste of an AlN bonding agent with 10 wt % Y₂O₃ can be used as a bonding agent. For example, the paste of the AlN bonding agent can be applied to the interface between the upper surface of the cylindrical portion 131 and the lower surface 113 of the ceramic base member 110 at a thickness of 15 μm, and then joined by heating at 1700° C. for 1 hour while applying a force of 5 kPa in the direction perpendicular to the upper surface 111 (longitudinal direction of shaft 130). Alternatively, the upper surface of the cylindrical portion 131 and the lower surface 113 of the ceramic base member 110 can be fixed by screwing or brazing.

### EXAMPLES

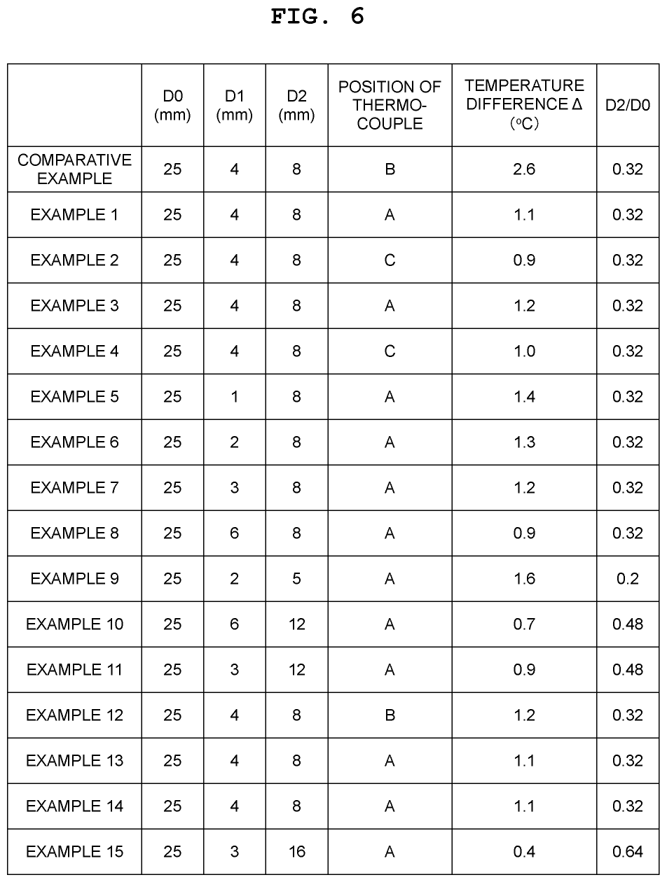

The present disclosure will be further explained using Examples 1 to 15. However, the present disclosure is not limited to the examples described below. FIG. 6 indicates a table summarizing the results of the following comparative example and Examples 1-15.

### Example 1

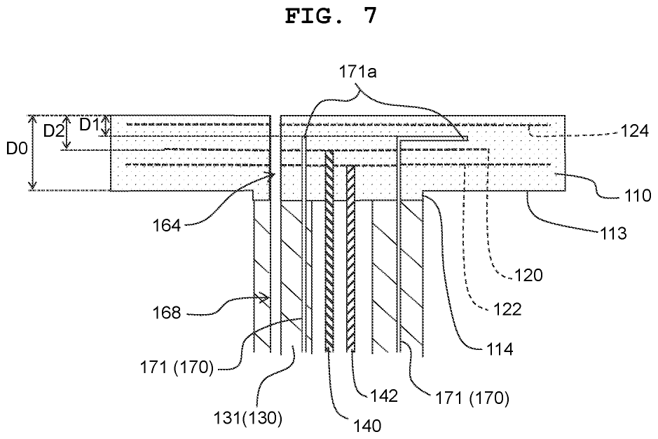

The ceramic heater 100 of Example 1 is described. In Example 1, the ceramic base member 110 with a diameter of 310 mm was prepared by the manufacturing method described above, using aluminum nitride (AlN) with 5 wt % sintering aid (Y₂O₃). As depicted in FIG. 7, the thickness D0 of the ceramic base member 110 is 25 mm. As the inner heater electrode 120, a molybdenum mesh (wire diameter 0.1 mm, mesh size #50, plain weave) was cut into the shape depicted in FIG. 3A. Similarly, the same molybdenum mesh was cut into the shape depicted in FIG. 3B as the outer heater electrode 122. The electrostatic adsorption electrodes 124 in the shape of FIG. 3C were formed, and these electrodes were embedded in the ceramic base member 110. The distance D2 (see FIG. 7) in the up-down direction from the upper surface 111 of the ceramic base member 110 to the inner heater electrode 120 is 8 mm. In Example 1, the ratio of the distance D2 to the thickness D0 of the ceramic base member 110 (D2/D0) is 0.32.

Three thermocouples 171 are embedded in the ceramic base member 110. The temperature-measuring contacts 171a at the tips of the three thermocouples 171 are located at positions A to C depicted in FIG. 3A, respectively. The distance D1 (see FIG. 7) in the up-down direction from the upper surface 111 of the ceramic base member 110 to the temperature-measuring contacts 171a is 4 mm. As depicted in FIG. 7, the portions of the TC-holes 170 in which the thermocouples 171 are located, extending in the radial direction orthogonal to the up-down direction, are located above the inner heater electrode 120 in the up-down direction.

The diameter of the opening 164a of the first gas flow path 164 is 3 mm. The center of the opening 164a is located 30 mm from the center of the ceramic base member 110. A ceramic heater 100 of such a shape was installed in a process chamber. Argon gas was supplied into the process chamber as the process gas at a pressure of 26600 Pa (200 Torr). Furthermore, the argon gas was adjusted to 6650 Pa (50 Torr) pressure through the first gas flow path 164.

Then, the temperature evaluation of the ceramic heater 100 was performed according to the following procedure. First, a silicon wafer for temperature evaluation was placed on the ceramic base member 110, and an undepicted external power supply was connected to the inner heater electrode 120 and the outer heater electrode 122 of the ceramic heater 100. Process gas and heat transfer gas were introduced at the above pressures, and the output power of the external power supply was adjusted so that the temperature of the ceramic base member 110 was maintained approximately 500° C. under steady state conditions. In Example 1, the temperature of the ceramic base member 110 was controlled using the thermocouple 171 with the temperature-measuring contact 171a at position A (see FIG. 3A) among the three thermocouples 171.

After the temperature of the ceramic base member 110 reached a steady state, the temperature distribution of the silicon wafer for temperature evaluation was measured using an infrared camera. In measuring the temperature distribution of the silicon wafer for temperature evaluation, the measurement area was defined as a 30 mm diameter area centered on the position on the upper surface of the silicon wafer for temperature evaluation corresponding to the position A where the temperature-measuring contact 171A used for temperature control of the ceramic base member 110 was located. The difference between the maximum and minimum temperatures within the measurement area was defined as the temperature difference A. The smaller the temperature difference A is, the more the temperature of the silicon wafer for temperature evaluation can be equalized without being affected by the heater electrode pattern. The silicon wafer for temperature evaluation is a silicon wafer of 300 mm diameter coated with a blackbody membrane of 30 μm thickness on its upper surface. The blackbody membrane is a film or a membrane with an emissivity (radiation factor) of 90% or higher, and can be deposited by coating with a blackbody paint mainly composed of carbon nanotubes, for example.

As described above, in Example 1, the temperature of the ceramic base member 110 was controlled by using one of the thermocouples 171 with the temperature-measuring contact 171a at position A (see FIG. 3A). In Example 1, the temperature difference A in the measurement area corresponding to position A of the silicon wafer for temperature evaluation was 1.1° C.

### Example 2

In Example 2, the temperature of the ceramic base member 110 was controlled by using one of the thermocouples 171 with the temperature-measuring contact 171a at position C (see FIG. 3A). Except for this point, Example 2 is similar to Example 1. In Example 2, the temperature difference A in the measurement area corresponding to position C of the silicon wafer for temperature evaluation was 0.9° C.

### Comparative Example

In a comparative example, the temperature of the ceramic base member 110 was controlled by using one of the thermocouples 171 with the temperature-measuring contact 171a at position B (see FIG. 3A). In other words, the temperature of the ceramic base member 110 was controlled by using one of the thermocouples 171 with the temperature-measuring contact 171a located at the position overlapping the inner heater electrode 120 in the up-down direction. Except for this point, the comparative example is similar to Example 1. In the comparative example, the temperature difference A in the measurement area corresponding to position B of the silicon wafer for temperature evaluation was 2.6° C.

### Example 3

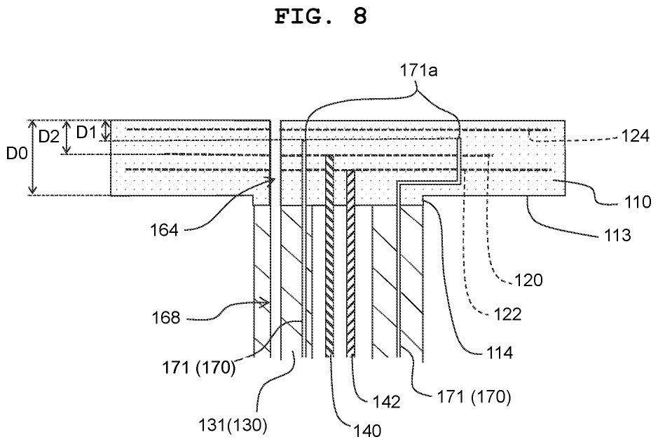

In Example 3, as depicted in FIG. 8, the portion of the TC-hole 170, in which the thermocouple 171 is located, extending in the radial direction orthogonal to the up-down direction, is located below the outer heater electrode 122 in the up-down direction. Except for this point, Example 3 is similar to Example 1. In Example 3, the temperature difference A in the measurement area corresponding to position A of the silicon wafer for temperature evaluation was 1.2° C.

### Example 4

In Example 4, as in Example 3, the portion of the TC-hole 170, in which the thermocouple 171 is located, extending in the radial direction orthogonal to the up-down direction is located below the outer heater electrode 122 in the up-down direction (see FIG. 8). In Example 4, the temperature of the ceramic base member 110 was controlled by using one of the thermocouples 171 with the temperature-measuring contact 171a at position C (see FIG. 3A). Except for these points, Example 4 is similar to Example 1. In Example 4, the temperature difference A in the measurement area corresponding to position C of the silicon wafer for temperature evaluation was 1.0° C.

### Example 5

In Examples 5-11, as in Example 1, the portion of the TC-hole 170, in which the thermocouple 171 is located, extending in the radial direction orthogonal to the up-down direction is located above the inner heater electrode 120 in the up-down direction (see FIG. 7). In Examples 5-11, the temperature of the ceramic base member 110 was controlled by using one of the thermocouples 171 with the temperature-measuring contact 171a at position A (see FIG. 3A). In Example 5, the distance D1 (see FIG. 7) in the up-down direction from the upper surface 111 of the ceramic base member 110 to the temperature-measuring contact 171 was 1 mm. Except for this point, Example 5 is similar to Example 1. In Example 5, the temperature difference A in the measurement area corresponding to position A of the silicon wafer for temperature evaluation was 1.4° C.

### Example 6

In Example 6, the distance D1 (see FIG. 7) in the up-down direction from the upper surface 111 of the ceramic base member 110 to the temperature-measuring contact 171 was 2 mm. Except for this point, Example 6 is similar to Example 1. In Example 6, the temperature difference A in the measurement area corresponding to position A of the silicon wafer for temperature evaluation was 1.3° C.

### Example 7

In Example 7, the distance D1 (see FIG. 7) in the up-down direction from the upper surface 111 of the ceramic base member 110 to the temperature-measuring contact 171 was 3 mm. Except for this point, Example 7 is similar to Example 1. In Example 7, the temperature difference A in the measurement area corresponding to position A of the silicon wafer for temperature evaluation was 1.2° C.

### Example 8

In Example 8, the distance D1 (see FIG. 7) in the up-down direction from the upper surface 111 of the ceramic base member 110 to the temperature-measuring contact 171 was 6 mm. Except for this point, Example 8 is similar to Example 1. In Example 8, the temperature difference A in the measurement area corresponding to position A of the silicon wafer for temperature evaluation was 0.9° C.

### Example 9

In Example 9, the distance D2 (see FIG. 7) in the up-down direction from the upper surface 111 of the ceramic base member 110 to the inner heater electrode 120 was 5 mm, and the distance D1 (see FIG. 7) in the up-down direction from the upper surface 111 of the ceramic base member 110 to the temperature-measuring contact 171 was 2 mm. The ratio of the distance D2 to the thickness D0 of the ceramic base member 110 (D2/D0) is 0.2. Except for these points, Example 9 is similar to Example 1. In Example 9, the temperature difference A in the measurement area corresponding to position A of the silicon wafer for temperature evaluation was 1.6° C.

### Example 10

In Example 10, the distance D2 (see FIG. 7) in the up-down direction from the upper surface 111 of the ceramic base member 110 to the inner heater electrode 120 is 12 mm. The distance D1 (see FIG. 7) in the up-down direction from the upper surface 111 of the ceramic base member 110 to the temperature-measuring contact 171 is 6 mm. The thickness of the ceramic base member 110 is 6 mm. The ratio of the distance D2 to the thickness D0 of the ceramic base member 110 (D2/D0) is 0.48. Except for these points, Example 10 is similar to Example 1. In Example 10, the temperature difference A in the measurement area corresponding to position A of the silicon wafer for temperature evaluation was 0.7° C.

### Example 11

In Example 11, the distance D2 (see FIG. 7) in the up-down direction from the upper surface 111 of the ceramic base member 110 to the inner heater electrode 120 is 12 mm. The distance D1 (see FIG. 7) in the up-down direction from the upper surface 111 of the ceramic base member 110 to the temperature-measuring contact 171 is 3 mm. The ratio of the distance D2 to the thickness D0 of the ceramic base member 110 (D2/D0) is 0.48. Except for these points, Example 11 is similar to Example 1. In Example 11, the temperature difference A in the measurement area corresponding to position A of the silicon wafer for temperature evaluation was 0.9° C.

### Example 12

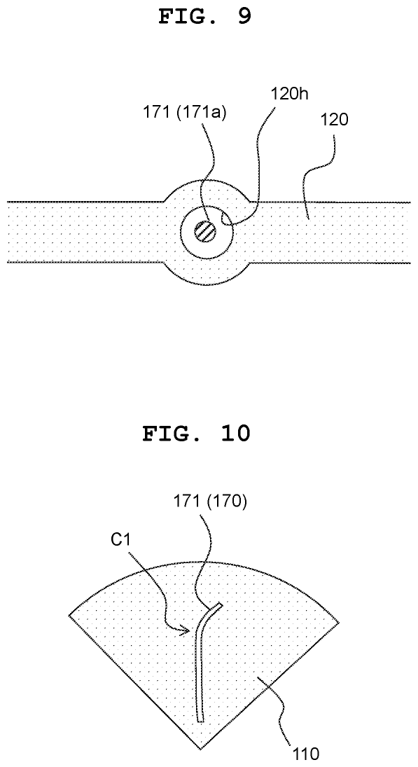

In Example 12, as in Example 1, the portion of the TC-hole 170, in which the thermocouple 171 is located, extending in the radial direction orthogonal to the up-down direction is located above the inner heater electrode 120 in the up-down direction (see FIG. 7). In Example 12, the temperature of the ceramic base member 110 was controlled by using one of the thermocouples 171 with the temperature-measuring contact 171a at position B (see FIG. 3A). However, to prevent the temperature-measuring contact 171a and the inner heater electrode 120 from overlapping in the up-down direction, an opening 120h was formed in the inner heater electrode 120 at the position overlapping the temperature-measuring contact 171a, as depicted in FIG. 9. As a result, the temperature-measuring contact 171a located at position B (see FIG. 3A) does not overlap with the inner heater electrode 120 in the up-down direction. Except for these points, Example 12 is similar to Example 1. In Example 12, the temperature difference A in the measurement area corresponding to position B of the silicon wafer for temperature evaluation was 1.2° C.

### Example 13

In Example 13, as in Example 1, the portion of the TC-hole 170, in which the thermocouple 171 is located, extending in the radial direction orthogonal to the up-down direction is located above the inner heater electrode 120 in the up-down direction (see FIG. 7). In Example 13, the portion of the TC-hole 170, in which the thermocouple 171 is located, extending in the radial direction orthogonal to the up-down direction has a curved portion C1 in the plane parallel to the upper surface 111 and the lower surface 113 of the ceramic base member 110 (in the horizontal plane), as depicted in FIG. 10. Except for this point, Example 13 is similar to Example 1. In Example 13, the temperature difference A in the measurement area corresponding to position A of the silicon wafer for temperature evaluation was 1.1° C.

### Example 14

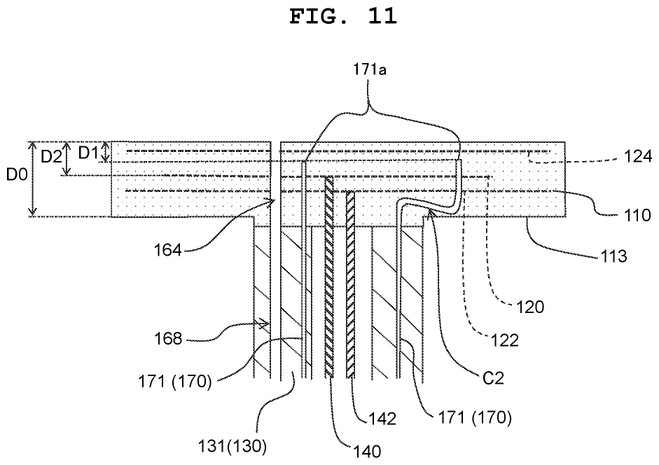

In Example 14, as in Example 3, the portion of the TC-hole 170, in which the thermocouple 171 is located, extending in the radial direction orthogonal to the up-down direction is located lower than the outer heater electrode 122 in the up-down direction (see FIG. 11). As depicted in FIG. 11, the portion of the TC-hole 170, in which the thermocouple 171 is located, extending in the radial direction orthogonal to the up-down direction is not parallel to the upper surface 111 and the lower surface 113 of the ceramic base member 110, and in Example 14, the portion extending in the radial direction orthogonal to the up-down direction of the TC-hole 170 where the thermocouple 171 is placed has a curved portion C2 in the plane parallel to the up-down direction, not parallel to the upper surface 111 and the lower surface 113 of the ceramic base member 110, as depicted in FIG. 11. Except for this point, Example 14 is similar to Example 1. In Example 14, the temperature difference A in the measurement area corresponding to position A of the silicon wafer for temperature evaluation was 1.1° C.

### Example 15

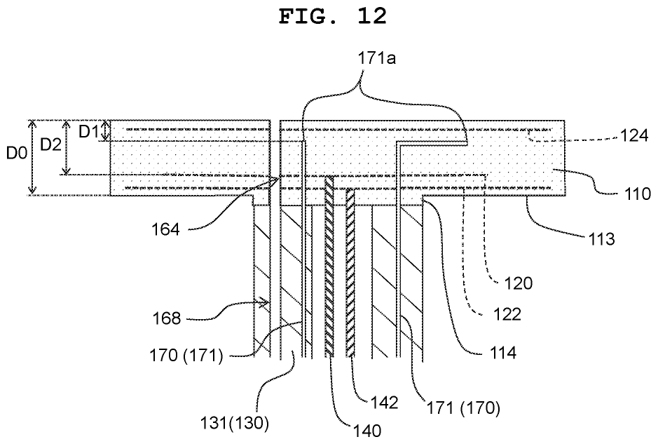

In Example 15, as in Example 1, the portion of the TC-hole 170, in which the thermocouple 171 is located, extending in the radial direction orthogonal to the up-down direction is located above the inner heater electrode 120 in the up-down direction (see FIG. 12). As depicted in FIG. 12, compared to Example 1 (see FIG. 7), the inner heater electrode 120 and the outer heater electrode 122 are buried at a greater distance from the upper surface 111 of the ceramic base member 110. Specifically, in Example 15, the distance D2 (see FIG. 7) in the up-down direction from the upper surface 111 of the ceramic base member 110 to the inner heater electrode 120 is 16 mm. The ratio of the distance D2 to the thickness D0 of the ceramic base member 110 (D2/D0) is 0.64. Except for this point, Example 15 is similar to Example 1. In Example 15, the temperature difference A in the measurement area corresponding to position A of the silicon wafer for temperature evaluation was 0.4° C.

### Technical Effects of Embodiments

In the above embodiments and Examples 1-15, the ceramic heater 100 includes a ceramic base member 110 and a plurality of heating elements (heater portions 122a of the inner heater electrode 120 and the outer heater electrode 122) embedded in the ceramic base member 110. The ceramic base member 110 is provided with the plurality of thermocouples 171. The temperature-measuring contacts 171a of the thermocouples 171 are embedded in the ceramic base member 110. Regarding at least one thermocouple 171 (e.g., the thermocouple 171 with the temperature-measuring contact 171a disposed at positions A and C (see FIG. 3A)), the temperature-measuring contacts 171a do not overlap with the heater portions 122a of the inner heater electrode 120 and the outer heater electrode 122 in the up-down direction. In other words, the temperature-measuring contact 171a overlaps the ceramic sintered body located between the heater electrodes 122 in the ceramic base member 110.

For example, as in positions A and C above, the temperature-measuring contacts 171a of the thermocouples 171 can be placed in a situation where it overlaps in the up-down direction with a crossing area where a plurality of gaps (GP1 to GP5) formed by the heater electrodes intersect (see Examples 1 to 11, 13 to 15). As in Example 12, the temperature-measuring contacts 171a of the thermocouples 171 can be arranged in a position overlapping in the up-down direction with an opening provided in the heater electrode.

As described above, in the comparative example, the temperature of the ceramic base member 110 was controlled by using one of the thermocouples 171, in which the temperature-measuring contact 171a was arranged in a position overlapping with the inner heater electrode 120 in the up-down direction. In this case, the temperature difference A within the measurement area defined as described above was relatively large (2.6° C.). In contrast, in Examples 1-15, the temperature of the ceramic base member 110 was controlled by using one of the thermocouples 171 in which the temperature-measuring contact 171a was located in a position not overlapping with the heater portion 122a of the inner heater electrode 120 and the outer heater electrode 122 in the up-down direction. In this case, the temperature difference A within the measurement area was kept within 1.6° C. This indicates that by controlling the temperature of the ceramic base member 110 using the thermocouple 171 with the temperature-measuring contact 171a positioned in a position where it does not overlap the heater portion 122a of the inner heater electrode 120 and the outer heater electrode 122 in the up-down direction, this method can contribute to improving the temperature uniformity of wafers, such as silicon wafers for temperature evaluation.

In this embodiment, the distance D1 in the up-down direction from the upper surface 111 of the ceramic base member 110 to the temperature-measuring contact 171 can be 1 mm≤D1≤4 mm. Generally, the temperature of the upper surface of the silicon wafer for temperature evaluation measured by an infrared camera is slightly lower than the temperature measured by the thermocouples 171 embedded in the ceramic base member 110. By setting the distance D1 in the up-down direction from the upper surface 111 of the ceramic base member 110 to the temperature-measuring contacts 171 to 1 mm≤D1≤4 mm, the temperature measured by the thermocouple 171 embedded in the ceramic base member 110 can be made closer to the temperature of the upper surface of the silicon wafer for temperature evaluation as measured by the infrared camera.

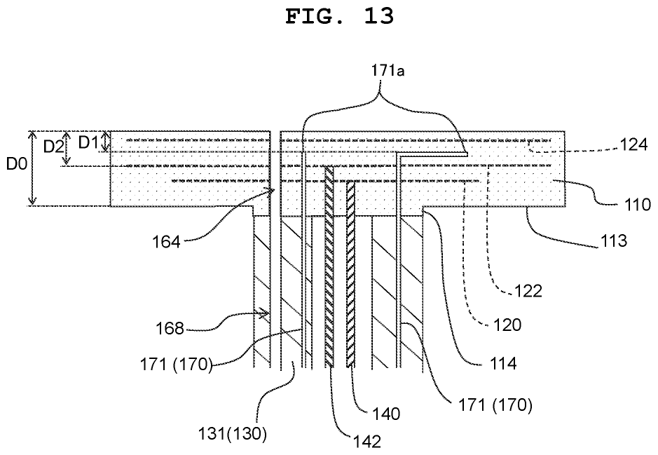

In this embodiment, the ratio D2/D0 of the distance D2 in the up-down direction from the upper surface 111 of the ceramic base member 110 to the inner heater electrode 120 to the thickness D0 of the ceramic base member 110 can be D2/D0≤0.4. The distance D1 in the up-down direction from the upper surface 111 of the ceramic base member 110 to the temperature-measuring contact 171 and the distance D2 in the up-down direction from the upper surface 111 of the ceramic base member 110 to the inner heater electrode 120 can be 1 mm≤D1≤D2. As described below, the outer heater electrode 122 can be placed higher than the inner heater electrode 120 (see FIG. 13). In this case, the ratio D2/D0 of the distance D2 in the up-down direction from the upper surface 111 of the ceramic base member 110 to the outer heater electrode 122 to the thickness D0 of the ceramic base member 110 can be D2/D0≤0.4. The distance D1 in the up-down direction from the upper surface 111 of the ceramic base member 110 to the temperature-measuring contact 171 and the distance D2 in the up-down direction from the upper surface 111 of the ceramic base member 110 to the outer heater electrode 122 can be 1 mm≤D1≤D2.

By moving the position where the heater electrode is buried closer to the upper surface 111 of the ceramic base member 110, the temperature controllability for the wafer to be heated can be improved. Therefore, the ratio D2/D0 of the distance D2 in the up-down direction from the upper surface 111 of the ceramic base member 110 to the heater electrode to the thickness D0 of the ceramic base member 110 should be small. The distance D1 in the up-down direction from the upper surface 111 of the ceramic base member 110 to the temperature-measuring contact 171 and the distance D2 in the up-down direction from the upper surface 111 of the ceramic base member 110 to the heater electrode are 1 mm≤D1≤D2. This allows the temperature-measuring contact 171 to be placed above the heater electrode. Furthermore, a sufficient gap can be secured between the temperature-measuring contact 171 and the upper surface 111 of the ceramic base member 110 for arranging, for example, an RF electrode.

In the above embodiment, the ratio D2/D0 of the distance D2 in the up-down direction from the upper surface 111 of the ceramic base member 110 to the heater electrode to the thickness D0 of the ceramic base member 110 can be 0.5≤D2/D0≤0.9. By moving the position where the heater electrode is buried away from the upper surface 111 of the ceramic base member 110, a sufficient area can be secured to form TC-holes 170 for placing the thermocouple 171 inside the ceramic base member 110.

In the above embodiment, the thermocouples 171 are wired in an area inside the outer diameter of the shaft 130. Specifically, a portion of the TC-holes 170 is formed in the cylindrical portion 131 of the shaft 130 for inserting the thermocouples 171. Because the shaft 130 is provided in the ceramic heater 100, the thermal insulation between the component connected to the shaft 130 and the ceramic base member 110 can be improved, and the uniformity of the wafer to be heated can be improved. Furthermore, since TC-holes 170 can be provided in the shaft 130, wiring of the thermocouples 171 becomes more manageable.

In this embodiment, as in Example 13, the portion of the TC-hole 170, in which the thermocouple 171 is located, extending in the radial direction orthogonal to the up-down direction, may have a curved portion in the horizontal plane. As in Example 14, the portion of the TC-holes 170, in which the thermocouples 171 are located, extending in the radial direction orthogonal to the up-down direction, may have a curved portion in the plane parallel to the up-down direction. In either case, when the thermocouples 171 are inserted into the TC-holes 170, the thermocouples 171 bend in contact with the wall surface of the TC-holes 170, causing elastic deformation. As a result, the temperature-measuring contacts 171a at the tips of the thermocouples 171 are pressed against the edge of the TC-holes 170, thereby improving the temperature measurement accuracy of the temperature-measuring contacts 171a. The curved portion formed in the TC-holes 170 does not necessarily have to be curved. For example, it may be a polygonal line. In this case, the same technical effect can be achieved.

### Modifications

The embodiments described above are only examples and may be modified as necessary. For example, using SUS-sheathed thermocouples as thermocouples 171 is not limited, but any thermocouples can be used. The temperature sensors are not limited to the thermocouples. For example, any temperature sensor can be used, such as a resistance temperature sensor, such as a platinum resistance element, or an optical type temperature sensor, such as an optical fiber thermometer, etc. The shape and cross-sectional shape of the TC-holes 170 can also be changed as needed to suit the temperature sensors. The shape and dimensions of the ceramic base member 110 and the shaft 130 are not limited to those of the above embodiments and can be changed as needed. The height, width, and other dimensions of the annular convex portion 152, the longitudinal cross-sectional shape, and the size of the surface roughness Ra of the upper surface 152a can be changed as needed. The height of the plurality of convex portions 156, the shape of the upper surface 156a, and the size of the surface roughness Ra of the upper surface 156a can be changed as needed. The arrangement of the plurality of convex portions 156 can also be changed as needed.

In the above embodiments, molybdenum, tungsten, and alloys containing molybdenum and/or tungsten were used as heater electrodes, but the present disclosure is not limited to such a manner. For example, metals or alloys other than molybdenum and tungsten can be used. The shape (pattern) and arrangement of the heater electrodes can also be changed as needed. For example, as depicted in FIG. 13, the outer heater electrode 122 can be placed above the inner heater electrode 120. In this case, the distance between the heater portion 122a of the outer heater electrode 122, which heats the outer circumference of the wafer to be heated, and the wafer to be heated can be made closer. Therefore, the temperature control of the outer circumference of the wafer to be heated becomes easier.

In the above embodiment, the ceramic heater 100 is provided with a shaft 130, but the disclosure is not limited to such a manner, and the ceramic heater 100 does not necessarily have to be provided with a shaft 130. Even if the ceramic heater 100 has a shaft 130, the second gas flow path 168 extending in the up-down direction may not be formed in the cylindrical portion 131 of the shaft 130. For example, instead of the second gas flow path 168, a separate gas piping can be provided in the hollow region of the cylindrical portion 131 (where the feeder wire 140 is provided). Similarly, there is no need to provide the TC-holes 170 in which the thermocouple 171 is placed inside the cylinder of the cylindrical portion 131, for example, the thermocouples 171 can be wired in the hollow region of the cylindrical portion 131.

Although the disclosure has been described above using the embodiments and modified embodiments of the disclosure, the technical scope of the disclosure is not limited to the above-described scope. It is obvious to those skilled in the art to make various changes or improvements to the above embodiments. It is clear from the description of the claims that forms with such changes or improvements can also be included in the technical scope of the disclosure.

The order of execution of each process in the manufacturing method depicted in the description and drawings is not specified in particular order, and can be executed in any order unless the output of the previous process is used in a subsequent process. For convenience, using “first,” “next,” and the like in the explanation does not mean executing in this order is mandatory.

The present disclosure may include the following addenda 1 to 10.

### Addendum 1

A ceramic heater including: a ceramic base member including: an upper surface and a lower surface opposite to the upper surface in an up-down direction; a plurality of heating elements embedded in the ceramic base member; and a plurality of temperature sensors each including a temperature sensing portion embedded in the ceramic base member, wherein the temperature sensing portion of at least one of the plurality of temperature sensors is positioned in a location not overlapping with the plurality of heating elements in the up-down direction.

### Addendum 2

The ceramic heater according to Addendum 1, wherein a distance D1 in the up-down direction between the upper surface of the ceramic base member and the temperature sensing portion of the at least one of the plurality of the temperature sensors satisfies 1 mm≤D1≤4 mm.

### Addendum 3

The ceramic heater according to Addendum 1 or 2, wherein a length DO in the up-down direction of the ceramic base member, the distance D1, and a distance D2 in the up-down direction between the upper surface of the ceramic base member and the at least one of the heating elements satisfy D2/D0≤0.4 and 1 mm≤D1≤D2.

### Addendum 4

The ceramic heater according to Addendum 1 or 2, wherein a length DO in the up-down direction of the ceramic base member and a distance D2 in the up-down direction between the upper surface of the ceramic base member and the at least one of the heating elements satisfy 0.5≤D2/D0≤0.9.

### Addendum 5

The ceramic heater according to any one of Addenda 1 to 4, wherein the plurality of heating elements is arranged to form a plurality of gaps, the temperature sensing portion of the at least one of the temperature sensors is arranged to overlap in the up-down direction with a crossing region in which the plurality of gaps intersects.

### Addendum 6

The ceramic heater according to any one of Addenda 1 to 5, wherein at least one of the plurality of heating elements includes an opening, and the temperature sensing portion of the at least one of the plurality of temperature sensors is arranged to overlap with the opening in the up-down direction.

### Addendum 7

The ceramic heater according to any one of Addenda 1 to 6, further comprising a shaft joined to the lower surface of the ceramic base member, wherein the plurality of temperature sensors is wired in an area located inside of an outer diameter of the shaft.

### Addendum 8

The ceramic heater according to any one of Addenda 1 to 7, wherein the ceramic base member includes a plurality of holes in which the plurality of temperature sensors is arranged, and a hole, among the plurality of holes, in which the at least one of the temperature sensors is arranged includes a first curved portion extending in a curved or polygonal line in a horizontal direction orthogonal to the up-down direction.

### Addendum 9

The ceramic heater according to any one of Addenda 1 to 8, wherein the ceramic base member includes a plurality of holes in which the plurality of temperature sensors is arranged, and a hole, among the plurality of holes, in which the at least one of the temperature sensors is arranged includes a second curved portion extending in a curved or polygonal line in the up-down direction.

### Addendum 10

The ceramic heater according to any one of Addenda 1 to 9, wherein the plurality of heating elements includes: an outer heating element embedded in a peripheral portion of the ceramic base member; and an inner heating element embedded inside and below the outer heating element, a distance in the up-down direction between the temperature sensing portion of the at least one of the plurality of the temperature sensors and the outer heating element is smaller than a distance in the up-down direction between the temperature sensing portion of the at least one of the temperature sensors and the inner heating element.

What is claimed is:

1. A ceramic heater comprising:
a ceramic base member including: an upper surface and a lower surface opposite to the upper surface in an up-down direction;
a plurality of heating elements embedded in the ceramic base member; and
a plurality of temperature sensors each including a temperature sensing portion embedded in the ceramic base member, wherein
the temperature sensing portion of at least one of the plurality of temperature sensors is positioned in a location not overlapping with the plurality of heating elements in the up-down direction.

2. The ceramic heater according to claim 1, wherein
a distance D1 in the up-down direction between the upper surface of the ceramic base member and the temperature sensing portion of the at least one of the plurality of the temperature sensors satisfies 1 mm≤D1≤4 mm.

3. The ceramic heater according to claim 2, wherein
a length D0 in the up-down direction of the ceramic base member, the distance D1, and a distance D2 in the up-down direction between the upper surface of the ceramic base member and the at least one of the heating elements satisfy D2/D0≤0.4 and 1 mm≤D1≤D2.

4. The ceramic heater according to claim 2, wherein
a length D0 in the up-down direction of the ceramic base member and a distance D2 in the up-down direction between the upper surface of the ceramic base member and the at least one of the heating elements satisfy 0.5≤D2/D0≤0.9.

5. The ceramic heater according to claim 1, wherein
the plurality of heating elements is arranged to form a plurality of gaps,
the temperature sensing portion of the at least one of the temperature sensors is arranged to overlap in the up-down direction with a crossing region in which the plurality of gaps intersects.

6. The ceramic heater according to claim 1, wherein at least one of the plurality of heating elements includes an opening, and
the temperature sensing portion of the at least one of the plurality of temperature sensors is arranged to overlap with the opening in the up-down direction.

7. The ceramic heater according to claim 1, further comprising a shaft joined to the lower surface of the ceramic base member, wherein
the plurality of temperature sensors is wired in an area located inside of an outer diameter of the shaft.

8. The ceramic heater according to claim 1, wherein
the ceramic base member includes a plurality of holes in which the plurality of temperature sensors is arranged, and
a hole, among the plurality of holes, in which the at least one of the temperature sensors is arranged includes a first curved portion extending in a curved or polygonal line in a horizontal direction orthogonal to the up-down direction.

9. The ceramic heater according to claim 1, wherein
the ceramic base member includes a plurality of holes in which the plurality of temperature sensors is arranged, and
a hole, among the plurality of holes, in which the at least one of the temperature sensors is arranged includes a second curved portion extending in a curved or polygonal line in the up-down direction.

10. The ceramic heater according to claim 1, wherein
the plurality of heating elements includes:
an outer heating element embedded in a peripheral portion of the ceramic base member; and
an inner heating element embedded inside and below the outer heating element,
a distance in the up-down direction between the temperature sensing portion of the at least one of the plurality of the temperature sensors and the outer heating element is smaller than a distance in the up-down direction between the temperature sensing portion of the at least one of the temperature sensors and the inner heating element.
